(19) United States
(12) Patent Application Publication
(10) Pub. No.: US 2013/0185007 A1
(43) Pub. Date: Jul. 18, 2013

(54) METHOD AND CONFIGURATION FOR ESTIMATING THE EFFICIENCY OF AT LEAST ONE BATTERY UNIT OF A RECHARGEABLE BATTERY

(71) Applicants: Arpad Imre, Vaihingen (DE); Alexander Schmidt, Donaueschingen (DE); Matthias Bitzer, Stuttgart (DE)

(72) Inventors: Arpad Imre, Vaihingen (DE); Alexander Schmidt, Donaueschingen (DE); Matthias Bitzer, Stuttgart (DE)

(73) Assignee: ROBERT BOSCH GmbH, Stuttgart (DE)

(21) Appl. No.: 13/812,045

(22) PCT Filed: Jul. 4, 2011
(86) PCT No.: PCT/EP2011/061233

§ 371 Date: Apr. 3, 2013

(30) Foreign Application Priority Data
Jul. 29, 2010 (DE) 10 2010 038 646.4

(51) Int. Cl. G01R 31/36

(52) U.S. Cl. CPC G01R 31/3627
USPC 702/63

(57) ABSTRACT

The state of charge of at least one battery unit of a rechargeable battery is initially estimated, and at least one variable of the battery unit which describes the state of health of this battery unit at a selected operating point with the aid of a model is estimated. The variable describing the state of health is an instantaneous charge capacity of the battery unit, which is estimated from the load current of the battery unit at the operating point and the reciprocal value of the derivation over time of the previously estimated state of charge of the battery unit.

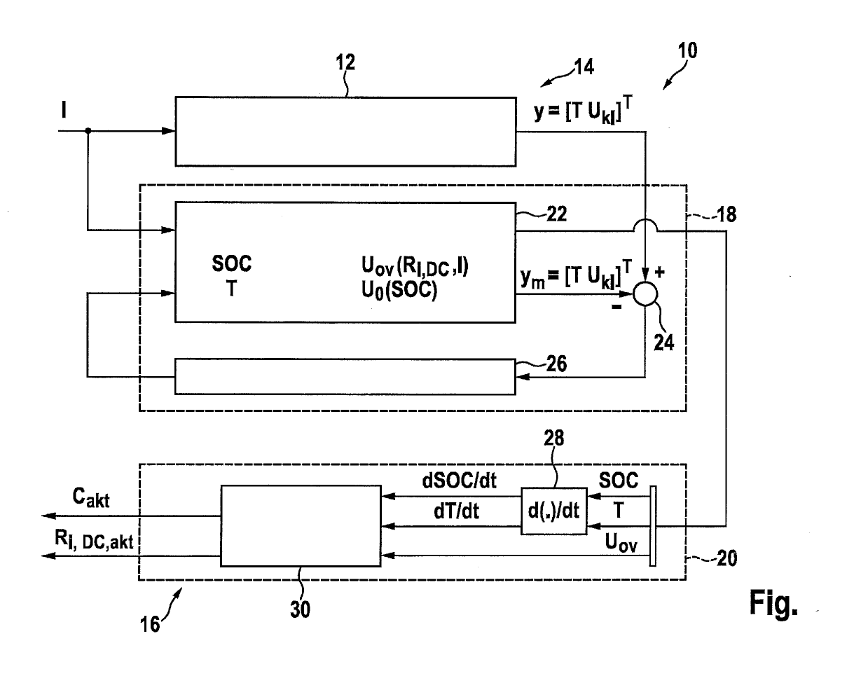

### BACKGROUND OF THE INVENTION

1. Field of the Invention

The present invention relates to a method for estimating the state of charge of at least one battery unit of a rechargeable battery and at least one variable of the battery unit describing the state of health of this battery unit at a selectable operating point with the aid of a model, in particular a mathematical model of the battery or at least of the battery unit, the state of charge being initially estimated. The present invention also relates to a configuration for estimating the charge of at least one battery unit of a rechargeable battery and at least one variable of the battery unit describing the state of health of this battery unit at a selectable operating point, having the battery unit and a model, in particular a mathematical model, implemented in a computation unit of the configuration of the battery or at least of the battery unit, a first state estimator initially estimating the state of charge with the aid of the model.

2. Description of the Related Art

For reducing the (local) emissions of motor vehicles, hybrid drive concepts or purely electric drive concepts are presently being developed to an increasing extent. The operation of electric machines in motor and generator operation of such drive concepts presupposes at least one electrical energy store such as a rechargeable battery in the vehicle. Lithium ion cells are favored for mobile and stationary storage of electrical energy, i.e., electrical energy stores, due to their high energy density in comparison with other battery systems. To utilize the installed storage capacity as thoroughly as possible, the input/output behavior of the battery and of its battery units are predicted under certain load profiles, i.e., corresponding charging and discharging currents with the aid of mathematical models. This is typically done using a so-called state estimator, which compares measured and simulated variables and calculates from them the instantaneous state of charge (SOC), for example. However, degradation effects pertaining to the performance and capacity of the store are disregarded in this procedure.

Published European patent application document EP 01 231 476 A3 describes a method as mentioned at the outset and a corresponding configuration for estimating the state of charge of a battery unit of a rechargeable battery and at least one variable of the battery unit describing the state of health of this battery unit at a selectable operating point with the aid of a model of the battery or at least of its battery unit, in which the state of charge is initially estimated. In this method, in addition to the instantaneous state of charge (SOC), another variable is estimated which describes the instantaneous efficiency and the instantaneous state of health (SOH).

### BRIEF SUMMARY OF THE INVENTION

The method according to the present invention offers the advantage that the estimation of the variable describing the state of health of the battery unit is an instantaneous determination of this variable which is independent of the load case.

According to the present invention it is provided in this regard that the variable describing the state of health is an instantaneous charge capacity Cₐₖₜ of the battery unit which is estimated from load current I_{B} of the battery unit at the operating point and the reciprocal value of the derivation over time of the previously estimated state of charge (SOC) of the battery unit.

Such a concept makes it possible to determine the efficiency and residual capacity of an electrical energy store, in particular a battery, in relation to the new condition, directly from the estimated state variables of a state estimator. The instantaneous state of health (SOH) of the store may therefore be determined at any point in time, based on characteristic parameters. Thus at a known initial capacity C₀, only two successive time increments k and k+1 in time interval Δt are sufficient to determine the derivation over time of the previously estimated state of charge with the aid of the differential quotient:

dSOC/dt=(SOC(k+1)−SOC(k))/Δt.

It is preferably provided here that instantaneous charge capacity Cₐₖₜ is estimated according to the equation:

Cₐₖₜ=k1·I_{B}·1/(dSOC/dt)

where k1 is a battery-type-specific constant.

The charge state of health SOH_{Q} is defined as a measure of the residual capacity, i.e.

SOH_{Q}=Cₐₖₜ/C₀

where C₀ is the capacity of the new cell and Cₐₖₜ is that of the aged cell at the point in time in question.

In general, the state of charge of a storage unit of any electrical (energy) store and at least one variable describing the state of health of this storage unit may be estimated with the aid of this method. The electrical store is in particular the aforementioned rechargeable battery, i.e., a battery or an element which stores electrical energy with the aid of electrochemical processes or a purely capacitive store, preferably a storage capacitor or a double-layer capacitor.

In general, the battery unit may be a single battery cell, a configuration of parallel and/or series connected battery cells or the entire battery. In particular, however, it is provided that the battery unit is a battery cell. The efficiency of each individual battery cell is therefore preferably estimated separately.

According to an advantageous embodiment of the present invention, it is provided that another one of the variables describing the state of health is instantaneous internal resistance R_{i,DC,B,akt} of the battery unit, which is estimated from an ascertained overpotential U_{OV} and load current I_{B} of the battery unit at the operating point. An operating point is defined by the presently required load current I_{B}, instantaneous state of charge (SOC) of the battery unit and temperature T_{∞} of the environment and temperature T of the battery unit itself.

It is preferably provided here that instantaneous internal resistance R_{i,DC,B,akt} of the battery unit is estimated according to the equation:

R_{i,DC,B,akt}=U_{OV,B}/(q3·I_{B})

where q3 is a parameter, which is known from offline parameterization and is characteristic for the specific battery unit.

According to another advantageous embodiment of the present invention, it is provided that overpotential U_{OV} of the battery unit is estimated from load current I_{B} of the battery unit at the operating point, the derivation over time of ascertained temperature T and a function f(T) of the battery unit describing the heat transport. Instantaneous internal resistance R_{i,DC,B,akt} may be determined as an additional variable describing the state of health with the aid of this overpotential U_{OV}—as already stated. Instead of instantaneous internal resistance R_{i,DC,B,akt} overpotential U_{OV}, which occurs at a certain load current, may also be used as a measure of efficiency. The corresponding power state of health SOH_{P} is defined as

SOH_{P}=(R_{i,DC,akt}/R_{i,DC,0})⁻¹

or

SOH_{P}=(U_{OV,akt}/U_{OV,0})⁻¹.

It is provided in particular that overpotential U_{OV} is estimated according to the equation

U_{OV,B}(R_{i,DC,B}, I_{B})=1/I_{B}·(dT/dT+k2·f(T))

where k2 is another battery-type-specific constant.

According to another advantageous embodiment of the present invention, it is provided that a variable describing the state of charge SOC_{B} of the battery unit at the operating point may be determined from the sum of a resting potential U₀, which depends on the state of health, and a load-dependent overpotential U_{OV} of the battery unit, i.e.,

SOC_{B}=1/q2·((y2−U_{OV}(R_{i,DC,B,akt}, I_{B}))−q1)

where q1, q2 are two additional parameters which are estimated as part of offline parameterization.

According to another advantageous embodiment of the present invention, it is provided that the battery model describes the following variables and functional relationships:
(a) the (physical) state of charge SOC,
(b) resting potential U₀ as a function of state of charge SOC,
(c) temperature T of the battery unit,
(d) overpotential U_{OV} under load and
(e) terminal voltage Uₖ₁ of the battery unit as the sum of the resting potential and the overpotential.

According to another advantageous embodiment of the method according to the present invention, it is provided that the state of charge SOC is estimated with the aid of a state estimator. It is provided in particular that this state estimator is a state estimator according to Kalman or a state observer according to Luenberger. The Kalman approach (the Kalman filter) is based on a state space modeling, in which a distinction is made explicitly between the dynamics of the system state and the process of its measurement. The state vector of a system is often understood to be the smallest set of determination items which describe the system with adequate accuracy and is represented within the scope of the model formation in the form of a multidimensional vector with corresponding dynamic equations, the so-called state space model. The Luenberger approach and also the Kalman approach are based on a comparison of the output variables of the state estimator with those of the controlled system. In doing so, the difference between the measured value of the system and the estimated output of the observer is attributed to the model. The observer is derived from the model of the system and a correction term which leads the state vector to the true state vector of the system by comparison of the system output and the estimated output of the model. The correction term, also referred to as return amplification, may be determined according to Kalman with the aid of a stochastic approach based on the assumption of measurement noise and process noise or according to Luenberger with the aid of a deterministic approach. The fundamental control structure is identical in both cases. The observer/state estimator is thus able to compensate for interferences such as measurement noise and process noise or model uncertainties, and the state vector of the model converges toward that of the system.

The configuration according to the present invention offers the advantage that the estimate of the variable describing the state of health, which is made up of the capacity state of health SOH_{Q} and the power state of health SOH_{P} of the battery unit, is an instantaneous determination of this variable, which is independent of the load case.

According to the present invention, it is provided in the configuration that the variable describing the capacity state of health SOH_{Q} includes instantaneous charge capacity Cₐₖₜ of the battery unit, and the configuration has a state of health estimator (SOH estimator), which is equipped to estimate this charge capacity Cₐₖₜ from load current I_{B} of the battery unit at the operating point, a battery-type-specific constant and the reciprocal value of the derivation over time of the state of charge SOC of the battery unit as previously estimated.

It is advantageously also provided that the variable describing the power state of health SOH is instantaneous internal resistance R_{i,DC,B,akt} or overpotential U_{OV,B} of the battery unit. The state of health estimator is also equipped to estimate overpotential U_{OV} of the battery unit from load current I_{B} of the battery unit at the operating point, the derivation over time of ascertained temperature T and a function f(t) of the battery unit describing the heat transport. As stated, instantaneous internal resistance R_{i,DC,B,akt} may be determined as an additional variable describing the state of health with the aid of this overpotential U_{OV}. Overpotential U_{OV} occurring at a certain load current may also be used instead of instantaneous internal resistance R_{i,DC,B,akt}, as a measure of efficiency.

It is preferably provided that both the state estimator and the state of health estimator (SOH estimator) are implemented in the computation unit of the configuration.

According to an advantageous embodiment of the configuration according to the present invention, it is provided that the state estimator is a state estimator according to Kalman or a state observer according to Luenberger. The state estimator according to Kalman is preferably a state variable filter. Alternatively, the state estimator also functions according to another method, for example, the “unscented transformation” method, i.e., as an unscented Kalman filter (UKF).

### BRIEF DESCRIPTION OF THE DRAWING

The FIGURE shows a schematic diagram of a configuration for estimating the state of charge and the state of health of an electrical store designed as a rechargeable battery according to a preferred specific embodiment of the present invention.

### DETAILED DESCRIPTION OF THE INVENTION

The FIGURE shows a block diagram of a configuration 10 for estimating the state of charge of a battery unit 12 of at least one rechargeable battery 14 and at least one variable of battery unit 12 describing the state of health of this battery unit 12. In addition to battery unit 12, configuration 10 also has a computer unit 16 in which a state estimator 18 and a state of health estimator (SOH estimator) 20 are implemented. State estimator 18 is typically designed as a state of charge estimator (SOC estimator). State of health estimator 20 is connected downstream from state estimator 18. State estimator 18 has a model of battery unit 12, which pertains to at least the following variables: the (physical) state of charge SOC, overpotential U_{OV} under load as a function of internal resistance R_{i,DC,B} and load current I, temperature T of the battery unit and resting potential U₀ as a function of state of charge SOC.

The input variable of battery unit 12 and of assigned model 22 is load current I. Corresponding output variables y=[TUₖ₁]^{T} of battery unit 12 and model 22 are compared with the aid of a comparator 24, and the result of the comparison is fed to model 22 as an additional input value via return amplification (correction term) 26. This yields a closed control circuit.

The output variables of the state estimator include (i) temperature T and (ii) terminal voltage Uₖ₁. The SOC as an internal state variable, temperature T as an output variable and overpotential U_{OV} (according to the aforementioned equation for estimating overpotential U_{OV}) are fed to SOH estimator 20. These variables—state of charge SOC and temperature T—are derived as a function of time in SOH estimator 20 with the aid of a (time-discrete) differentiator 28. The results of these derivations over time of state of charge SOC and temperature T are fed—along with overpotential U_{OV}—to a device 30 for inverting the model and, if necessary, for carrying out a least squares method (LSQ) within SOH estimator 20. This device 30 ascertains from these results the variables Cₐₖₜ and/or R_{i,DC,B,akt} which describe state of health SOH of battery unit 12.

It is advantageous in general for variables dSOC/dt and dT/dt to be averaged over a time interval of several time increments and I=const., and only then to determine values Cₐₖₜ and/or R_{i,DC,B,akt}. Depending on the model structure, Cₐₖₜ and/or R_{i,DC,B,akt} are calculated directly or are determined via a least squares method (LSQ).

The relationships are to be discussed below using the example of a battery unit 12 designed as a battery cell of a rechargeable battery, in particular a Li-ion battery:

For example, capacity C and internal resistance R_{i,DC} are introduced as a measure of the remaining power and capacity of an electrochemical battery cell. Internal resistance takes into account the purely ohmic contribution of various effects, which result in a voltage drop of terminal voltage Uₖ₁ of the cell under load. Since the upper and lower breakdown voltage must always be maintained for safety reasons with Li-ion cells, the voltage drop resulting from R_{i,DC} is characteristic for the power performance of battery 14. Alternatively, overpotential U₀ which occurs at a certain load current may also be used for the power consideration.

Capacity state of health SOH_{Q} is defined as a measure of the residual capacity, as already mentioned, i.e.,

SOH_{Q}=Cₐₖₜ/C₀ (1)

where C₀ is the capacity of the new cell and Cₐₖₜ is the capacity of the aged cell at the point in time in question.

Similarly, the power state of health SOH is defined as

SOH_{P}=(R_{i,DC,akt}/R_{i,DC,0})⁻¹ (2)

or

SOH_{P}=(U_{OV,akt}/U_{OV,0})⁻¹ (2′)

The calculation of variables Cₐₖₜ and _{OV,akt} or R_{i,DC,akt} is carried out as follows as an example of a simple physical storage model 22. The schematic procedure is illustrated in the FIGURE.

Storage model (battery model) 22 may be considered as follows: input variable u is load current I, so the state space model is then:

dSOC/dt=k1·(1/C)·I (3)

dT/dt=−k2·f(T)+U_{OV}(R_{i,DC}, I)·I (4)

The output variables of model 22 include y1 for temperature T and y2 for terminal voltage Uₖ₁=U₀(SOC)+U₀(R_{i,DC},l).

Constants k1 and k2 here are battery type-specific constants; function f(T) is a function which describes the removal of heat (e.g., with the aid of free convection, radiation, thermal conduction). C is the capacity and R_{i,DC} is the internal resistance of the rechargeable battery. Since temperature T is directly measurable, the observation task for this is trivial. In general, state estimator 18 (SOC estimation in the FIGURE) ascertains (internal) variables SOC and T from u, y1 and y2.

The question now arises as to whether capacity C and internal resistance R_{i,DC} may be determined unambiguously from the available measurement information. The following assumptions have been made for this reason:

The parameterization including (C₀, R_{i,DC,0} of the model for a new battery unit, in particular a battery cell, is known; the state estimator (SOC state estimator) 18 is convergent, i.e., the estimated states asymptotically approach those of the real system, and linearization of second output variable y2 at the operating point (I_{B}, T_{B}, SOC_{B}, R_{i,DC,B}) yields:

y2_{B}=−q1+q2·SOC_{B}+q3·R_{i,DC,B}·I_{B} (5)

The variables being sought {Cₐₖₜ, R_{i,DC,akt}} may be determined according to the following scheme:
1. Directly ascertaining the overpotential from the definition of y1:

U_{OV,B}(R_{i,DC,B}, I_{B})=1/I_{B}·(dT/dt+k2·f(T)) (6)
2. This yields the instantaneous internal resistance as

R_{i,DC,B,akt}=U_{OV,B}/(q3·I_{B}) (7)
3. Similarly, the state of charge is obtained from (6) in (5):

SOC_{B}=1/q2·((y2−U_{OV}(R_{i,DC,B,akt}, I_{B}))−q1) (8)
4. Finally, the instantaneous capacity of the battery unit (in particular a cell) may be determined from (3)

Cₐₖₜ=k1·I_{B}·1/(dSOC/dt) (9)

Parameter pair {Cₐₖₜ, R_{i,DC,akt}} is unambiguously determinable from the available information using steps 1 through 4.

1-10. (canceled)

11. A method for estimating at least one variable of at least one battery unit of a rechargeable battery, the at least one variable describing the state of health of the battery unit at a selected operating point with the aid of a mathematical model of one of the rechargeable battery or the battery unit, the method comprising:
initially estimating a state of charge of the at least one battery unit of the rechargeable battery; and
estimating the variable describing the state of health as an instantaneous charge capacity of the at least one battery unit which is estimated based on a load current of the at least one battery unit at the selected operating point and a reciprocal value of a time derivative of the previously estimated state of charge of the at least one battery unit.

12. The method as recited in claim 11, wherein the at least one battery unit is a battery cell.

13. The method as recited in claim 12, wherein a further variable describing the state of health is estimated as an instantaneous internal resistance of the at least one battery unit based on an overpotential of the at least one battery unit and the load current of the at least one battery unit at the selected operating point.

14. The method as recited in claim 13, wherein the overpotential of the battery unit is estimated based on the load current of the battery unit at the selected operating point, a time derivative of an ascertained temperature, and a predetermined temperature function of the battery unit which describes a heat transport.

15. The method as recited in claim 11, wherein a variable describing the state of charge of the battery unit at the selected operating point is obtained from at least the sum of (i) a resting potential which depends on the state of health of the battery unit, and (ii) a load-dependent overpotential of the battery unit.

16. The method as recited in claim 15, wherein the battery model describes the following variables and functional relationships:
the state of charge of the at least one battery unit;
the resting potential as a function of the state of charge of the at least one battery unit;
the temperature of the at least one battery unit;
the load-dependent overpotential; and
a terminal voltage as the sum of the resting potential and the load-dependent overpotential.

17. The method as recited in claim 13, wherein the estimation of the state of charge (SOC) is carried out with the aid of a state estimator (18).

18. The method as recited in claim 17, wherein the state estimator is one of a state estimator according to Kalman or a state observer according to Luenberger.

19. A configuration for estimating a state of charge of at least one battery unit of a rechargeable battery and at least one variable of the battery unit describing a state of health of the at least one battery unit at a selected operating point, comprising:
a computer unit storing a mathematical model of one of the battery or the battery unit, the computer unit including:
a state estimator configured to initially estimate the state of charge with the aid of the stored model; and
a state-of-health estimator configured to estimate the variable describing the state of health of the battery unit as an instantaneous charge capacity of the battery unit based on a load current of the at least one battery unit at the selected operating point, a battery-type-specific constant, and a reciprocal value of a time derivative of the previously estimated state of charge of the at least one battery unit.

20. The configuration as recited in claim 19, wherein the state estimator is one of a state estimator according to Kalman or a state observer according to Luenberger.
